(19) United States
(12) Patent Application Publication
(10) Pub. No.: US 2021/0344549 A1
(43) Pub. Date: Nov. 4, 2021

(54) Data Compression and Transmission Technique

(71) Applicant: MemoScale AS, Trondheim (NO)

(72) Inventors: Kjetil Babington, Trondheim (NO); Rune Erlend Jensen, Trondheim (NO); Sindre Berg Stene, Trondheim (NO)

(73) Assignee: MemoScale AS, Trondheim (NO)

(21) Appl. No.: 17/246,708

(22) Filed: May 2, 2021

(30) Foreign Application Priority Data
May 1, 2020 (GB) GB2006450.7

(51) Int. Cl. H04L 29/06; H03M 7/30

(52) U.S. Cl. CPC H04L 29/0604; H03M 7/6011; H03M 7/3064; H04L 69/04

(57) ABSTRACT

Disclosed herein is a method of transmitting data, the method comprising: obtaining a plurality of data blocks; determining a plurality of values of a transmission parameter for a transmitter; determining a plurality of values of a processing parameter of a processor; determining, for each of the obtained data blocks, one of a plurality of compression levels in dependence on at least one of the determined transmission parameter values and/or at least one processing parameter values; compressing each of a plurality data blocks in dependence on the determined compression level each block; and transmitting the data blocks; wherein: the transmitted data blocks comprise data blocks are compressed with different compression levels; and one of the compression levels is a determination to not compress data blocks such that the method does not compress some of the transmitted data blocks.

### CROSS REFERENCE TO RELATED APPLICATION

The present application claims priority to Great Britain Patent Application No. 2006450.7, filed on May 1, 2020, which is incorporated herein by reference in its entirety.

### FIELD

The field of the invention is the transmission of data. Embodiments dynamically compress the data so as to reduce the overall transmission time of the data. Embodiments are particularly advantageous when the transmission rate of the data and/or the available processing resources for compressing data vary over the time period that the data is transmitted.

### BACKGROUND

The transmission of data over a transmission channel is required in a large number of applications.

It is known to compress all of the data before it is transmitted in order to reduce the amount of transmitted data. Known techniques include: minimizing the amount of transmitted data by compressing the data with a high compression ratio before the data is transmitted, using the same fixed compression level for all of the transmitted data and using a single streaming compression algorithm for all of the data. All of these known techniques have drawbacks when the available computing resources and transmission rates are variable. Sudden changes in available computing resources could potentially stall the transmission process because there is no available compressed data to send. A sudden drop in transmission rate may mean that more computing resources could have been spent on compression, reducing the total amount of data transferred.

There is a general need to improve on known techniques for compressing data before it is transmitted.

### SUMMARY

According to a first aspect of the invention, there is provided a method of transmitting data, the method comprising: obtaining a plurality of data blocks; determining a plurality of values of a transmission parameter for a transmitter; determining a plurality of values of a processing parameter of a processor; determining, for each of the obtained data blocks, one of a plurality of compression levels in dependence on at least one of the determined transmission parameter values and/or at least one processing parameter values; compressing each of a plurality data blocks in dependence on the determined compression level each block; and transmitting the data blocks; wherein: the transmitted data blocks comprise data blocks are compressed with different compression levels; and one of the compression levels is a determination to not compress data blocks such that the method does not compress some of the transmitted data blocks.

Preferably, the obtained data blocks are transmitted over a transmission time period; the plurality of transmission parameter values are determined at different times over the transmission time period; wherein the transmission parameter is a time variant parameter; and at least two of the transmission parameter values are different.

Preferably, each transmission parameter value comprises one or more components; and each component is determined in dependence on one or more of: measurements within the transmitter; a measured transmission rate of the transmitter; a transmission start time for a data block, the size of the transmitted data block and/or a transmission end time for the data block; data received in response to the transmission of one or more data blocks; link information; TCP/IP settings; ping time; determinations of an instantaneous, maximum, and/or average transmission rate; server and/or receiver provided settings; energy usage for transmission; variability of the transmission rate of a time period; historic data; geographical data; and user settings.

Preferably, the plurality of processing parameter values are determined at different times over the transmission time period; the processing parameter is a time variant parameter; and at least two of the processing parameter values are different.

Preferably, each processing parameter value comprises one or more components; and each component is determined in dependence on one or more of: the available processing resources for compressing a data block; a measured a compression rate; a compression start time for a data block, the size of the compressed data block, a compression ratio of the data block and/or a compression end time for the data block; data retrieved from the environment, such as by API calls obtaining information on any of CPU type, number of CPU cores, number of hardware threads, number of compression processes, CPU cache sizes, CPU frequency(s), performance setting, dedicated hardware blocks, thermal envelopes, battery state, AC/battery power, energy usage for compression/compute, historic data and user settings; initial setting data; a model; size of data to be compressed; number of blocks able to be processed; number of blocks that have been compressed but not transmitted; static compression rate estimates for each compression level; computed compression rate estimates for each compression level; an initial selection of how many compression processes to use; benchmark results; data type; a determination of the available processing resources for decompressing a data block at a receiver of the data blocks; and received information from the receiver of the data blocks, such as: the amount of processing resources available at the receiver, the progress the decompression at the receiver, remaining data waiting to be decompressed at the receiver, other descriptions of progress of decompression at the receiver, list of codecs available at the receiver and preferences of the receiver.

Preferably, each of the compression levels differ in the amount of processing resources required to compress a data block, the compression time for a data block and/or the compression ratio of a data block.

Preferably, each compression level corresponds to the use of a specific compression algorithm and/or specific compression parameters; and all of the compression levels correspond to the use of a different compression algorithm and/or compression parameters.

Preferably, the method further comprises estimating an available compression time for a data block in dependence on a transmission parameter value and/or a processing parameter value; and determining the compression level for the data block as the compression level that provides the largest reduction in the size of the data block within the estimated available compression time.

Preferably, the estimated available compression time is dependent on an estimated transmission time of one or more data blocks; and the estimated available compression time is determined as substantially the same as, or less than, the estimated transmission time.

Preferably, the estimated transmission time is dependent on: the number and/or size of data blocks in one or more of the compressor output queues; an estimated transmission end time of a block currently being transmitted; and/or the estimated transmission time of blocks in one or more of the compressor output queues and/or the transmission queue; and the method comprises determining a compression level for a data block in dependence on the estimated transmission time.

Preferably: the compression level for a data block is determined in dependence on the available resources for decompression at a receiver of the transmitted data blocks; and/or a received request for a compression level.

Preferably, the method further comprises selecting a plurality of data blocks in dependence on at least one of the determined values of the transmission parameter and/or at least one values of the processing parameter; wherein the compression levels are determined for the selected data blocks; and at least one of the selected data blocks for compression is one of the data blocks in a compressor output queue.

Preferably, the method further comprises: constructing a model in dependence on the determined values of the processing parameter and the determined values of the transmission parameter; and using the model to determine which data blocks are selected and/or the compression level for each selected block.

Preferably, the method further comprises: obtaining statistics on one or more of compression times, compression ratios and transmission rates; and constructing the model in dependence on the obtained statistics.

Preferably, the statistics are obtained for compression operations at each compression level; and the model uses the statistics to determine expected compression times and/or compression ratios for data blocks at each compression level; wherein the model estimates expected compression times and/or compression ratios for data blocks at a new compression level in dependence on the statistics of one or more existing compression levels.

Preferably, the compression levels for the data blocks are determined in dependence on an algorithm for minimising the transmission time period for the obtained data blocks.

Preferably, the processor is arranged to perform a plurality of compression operations; each data block is provided to at least one compression operation; and each compression operation is arranged to compress a data block in dependence on a compression level; wherein: each compression operation comprises one or more compression processes and a compressor output queue; all of the compression processes of a compression operation are arranged to compress a data block and then provide the compressed data block to the compressor output queue; and each compressor output queue may comprise one or more plurality of compressed data blocks.

Preferably, versions of the same obtained data block are compressed in a plurality of compression operations at a respective plurality of different compression levels; and the method further comprises removing a data block from a compressor output queue if another compressor output queue comprises a version of the same obtained data block with a larger compression ratio and/or at a higher compression level.

Preferably, the method further comprises: selecting one or more of the obtained data blocks for transmission; selecting one or more of the data blocks in the compressor output queues for transmission; and transmitting the selected data blocks; wherein the selection of a data block for transmission is dependent on one or more of: the compression level and/or compression ratio of the data blocks in the compressor output queues; order of the data blocks; a request for a data block; and values of the transmission parameter.

Preferably: the compression operations are controlled by a regulator; the regulator determines the performance of the compression operations; and one or more other processes are controlled in dependence on the determined the performance of the compression operations by the regulator; wherein the other processes may include any of the selection of a data block for compression, the supply of the obtained data blocks for transmission, the applied compression level, the provision of feedback to a user, the provision of feedback to the receiver and the selection of a compression algorithm.

Preferably the method further comprises receiving and selecting for transmission compressed versions of one or more of the obtained data blocks.

Preferably, the method further comprises: estimating a reduction of transmission time due to a compression operation on a data block, wherein the compression operation of the data block has not finished; and determining to allow the transmission of data to stall so as to allow a compressed data block by the compression operation to be transmitted if waiting for the compression operation to finish provides a sooner completion of data transmission than if a version of the same data block, that has not been compressed by the compression operation, is transmitted without the transmission of data stalling.

According to a second aspect of the invention, there is provided a method of transmitting data, the method comprising: obtaining a first set of data blocks; determining how to transmit the first set of data blocks according to the method of the first aspect; starting the transmission of the first set of data blocks; obtaining a second set of data blocks, wherein the second set of data blocks are obtained before the transmission of all of the first set of data blocks is finished; and determining, according to the method of any preceding claim, to how transmit the second set of data blocks and the data blocks in the first set of data blocks that have not been transmitted.

According to a third aspect of the invention, there is provided a processor and transmitter arranged to compress and transmit data blocks according to the method of the first or second aspects.

According to a fourth aspect of the invention, there is provided a computer program that, when executed, causes a computing system to perform the method of the first or second aspects.

### FIGURES

FIG. 1 shows a the relative amounts of transmission time and compression time in techniques according to embodiments;

FIG. 2 comprises performance results of techniques according to embodiments;

FIG. 3 comprises performance results of techniques according to embodiments;

FIG. 4 comprises performance results of techniques according to embodiments;

FIG. 5 is a flowchart of a process according to an embodiment;

FIG. 6 is a flowchart of a process according to an embodiment; and

FIG. 7 is a schematic diagram of processes that are performed according to an embodiment.

### EMODIMENTS

Embodiments provide techniques for dynamically compressing data so as to reduce the overall transmission time of the data. The amount of computing resources used to compress data is controlled in a way that reduces, preferably minimises, the total transfer time of the data.

According to embodiments, the data to be transmitted is divided into data blocks. Each data block may be, for example, a file or part of a file. The data blocks may all be the same size or have different sizes. The available computing resources for compressing a data block may vary over time. The transmission rate, which is the rate at which data may be transmitted over the transmission channel, may also vary over time. Embodiments vary the compression level applied to each data block in dependence on the available computing resources for compressing the data block. The applied compression level is also dependent on the current transmission rate. The variable compression levels applied are applied in a way that reduces, and preferably minimises, the overall transmission time of all of the data blocks. Some the transmitted data blocks may not be compressed if this results in an overall reduction in the transmission time.

Embodiments are fundamentally different from known techniques that are not directed towards minimising the overall transmission time of all of the data blocks. In particular, variations in the available computing resources for compressing data, and variations in the possible transmission rate, may result in the overall transmission time being reduced by compressing some data blocks before they are transmitted and not compressing some of the other data blocks before they are transmitted.

By contrast, the overall transmission time would not be reduced to the same extent by the known techniques of compressing all the data before transmission, minimizing the amount transmitted data, using a fixed compression level and using a single streaming compression algorithm for the data.

Embodiments are described in more detail below.

Embodiments provide a regulator for dynamically compressing data. A regulator is an algorithm, or model, that takes data as an input, selects a level of compression to compress data blocks with, and compresses the data so that at any time, some data is available to send, and preferably that data is already compressed at the time that it is sent.

Transferring data across a transmission channel, such as a network-link, is constrained by the current channel bandwidth. It is therefore advantageous to compress data before sending it if available computing resources can be used to compress the data (or parts of the data) without delaying the transfer. Furthermore, it is preferable to utilize all available/allocated computing resources to compress data as much as possible before the data is transmitted.

The regulator according to embodiments my use a number of (conceptual) queues.

The first queue “Q0” has uncompressed data, or the least compressed data. The second queue “Q1” contains data compressed at level 1. The third queue “Q2” contains data compressed at level 2, and so on with “Qn” containing data compressed at level n. There may be a total of N+1 queues.

A higher compression level indicates a higher amount of effort, i.e. amount of computing resources and/or computing time, expended on compression by computing resources and thereby implies that the data block size is more reduced. Accordingly, data compressed at level “Qn+1” may have a higher compression ratio than data compressed at level “Qn”.

The received data from a data source may be stored in Q0, i.e. the first queue. The received data may be raw data, that has not been compressed, or the received data may be data that has already been compressed by a separate process, for example it may be JPEG data. Accordingly, Q0 may store either uncompressed or compressed data. However, the data stored in Q0 is always less compressed than the data stored in any of the other queues, i.e. Q1 to QN.

A data transmission process is operating to transmit data. According to embodiments, whenever the transmission process is ready to send more data, it will choose the most heavily compressed available data block, and send that first. This means that several queues may comprise data at the same time, and the transmission process will take data from the queue comprising data blocks with the largest compression ratios.

A number of compression threads are operating. It is preferable that each compression thread gets, or selects, a compression task with a level of compression that will contribute to the transmission process being able to continuously send more heavily compressed data. Thus, when a compression thread is ready to start processing new data, the selected compression level to be used is estimated based on a model of how likely it is to finish the compression operation at that level before the transmission process would be able to finish sending all equally heavily compressed data.

The following is a description of an algorithm, which may be executed by a model, that the compression process may use to determine the compression level to use.

How fast the transmission process is successfully sending data, the “transfer rate estimate”, measured in MB/s, is continuously estimated.

How fast a compression thread is able to compress data blocks, measured in MB/s, is continuously calculated.

How long it takes for the transmission process to finish transmitting the data block that is currently being sent, using its size, time since transfer started, and the transfer rate estimate, may be calculated.

Starting with the queue comprising the most heavily compressed data blocks, given that transmission process is expected to send the most heavily compressed data blocks first, the transfer rate estimate and the sum of the compressed sizes of data blocks already in that queue are used to calculate how much time it would take the transmission process to finish sending those data blocks.

A candidate data block to be compressed, that is uncompressed or as little compressed as possible, is selected by starting at Q0 and checking in more compressed queues whenever a queue is empty, until the least compressed data block is found. A data block that is already in the process of being compressed is not selected for compression at a higher level, unless there are no other blocks available. The same block may therefore be compressed at several levels simultaneously. However, but the least compressed version of a data block is removed from a queue if/when a more compressed version of the same block becomes ready. If a block ends up in a queue for low compression while the average compression level for new blocks is high, the compression thread may choose to prioritize that older block with slightly less compression, over selecting an uncompressed block, in order avoid very old data blocks not being transmitted.

If the estimated time to send compressed data blocks in a queue is longer than the estimated time to compress the candidate data block, then the level of compression is selected based on this heavily compressed queue, and the compressing the candidate data block is started.

The algorithm can still choose to compress data blocks at this level if the queues at “Qn” and “Qn−1” contain an amount of compressed data sufficient to feed the transmission process (by taking data blocks from Qn then from Qn−1) long enough for the compression process to be able to finish compressing at level “n” before the sender thread runs out of data compressed at level n−1. Otherwise, the algorithm may determine to compress data at level n−1. Similarly, the same calculation may apply using queues Qn−1 and possibly Qn−2.

The algorithm should provide enough threads/compute resources to, on aggregate, compress data at, or faster than, the current transmission rate. Thus, if the compression throughput (compute or ratio) or transmission rate changes the level compression level target may change up or down dynamically. When selecting a compression level, the lowest level that can be selected that results in a compression process being applied to the data is level 1. If it is estimated that a compression process cannot finish compressing a data blocks to level 1 before the sending of all other data blocks has completed, then the algorithm may determine to not start the compression task, because it might stall the transmission process.

If the sender process regardless ends up stalling due to having to wait for the compression thread, then the compression process may be cancelled and the data sent in the previous state (i.e. sent uncompressed, or less compressed than if the compression thread had finished). The algorithm may also use estimates to calculate if it would be beneficial to let the compression process finish, even though the transmission process would stall because less data would have to be transferred, if the process is in a state where the reduction in data size would cause the transmission process to finish at an earlier time.

A determination may be made to stall the transmission process, rather than send data blocks immediately from Q0 (i.e. the least compressed data), if the stall is to wait only a short time for a compression process to complete.

It may be preferable to stop a compression process if the transmission process decides that sending the data block that is currently being processed is the best choice, in which case the data block will be sent in the state it was in prior to starting the compression process.

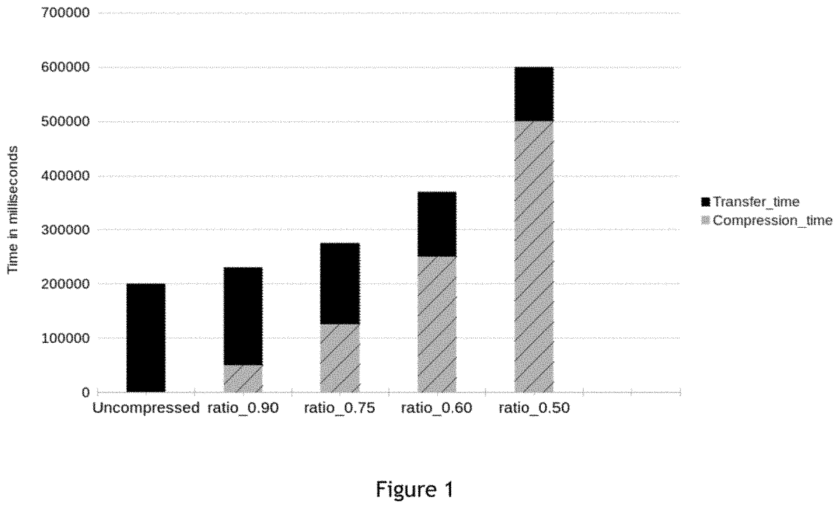

FIG. 1 shows the time to completion if data is first compressed and then transmitted, with various levels of compression.

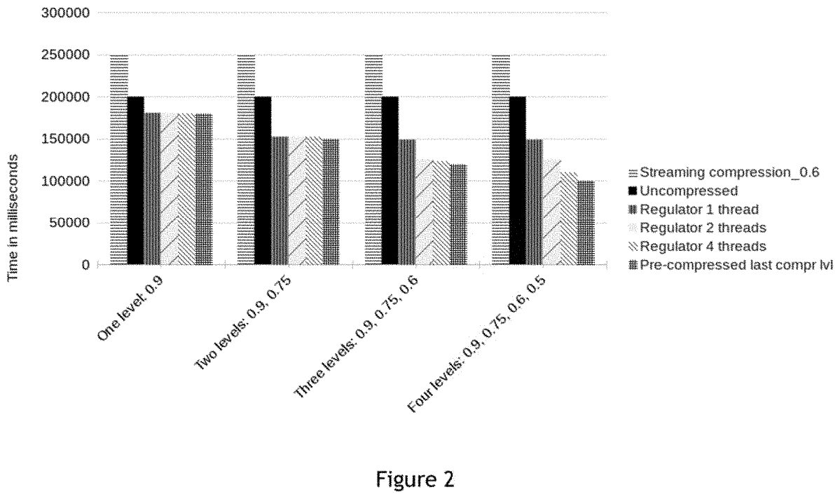

FIG. 2 shows the time to completion when using a compression effort regulator according to embodiments that dynamically targets lower total transmission time. The figure shows how the regulator performs with a different number of compression levels and threads. The compression ratios for the different levels are 0.9, 0.75, 0.6, and 0.5. The network transfer speed was 0.5 M B/s. The “pre-compressed last compr Lvl” bar shows the time it would take to upload the file if it was already compressed at the highest currently available level of the regulator.

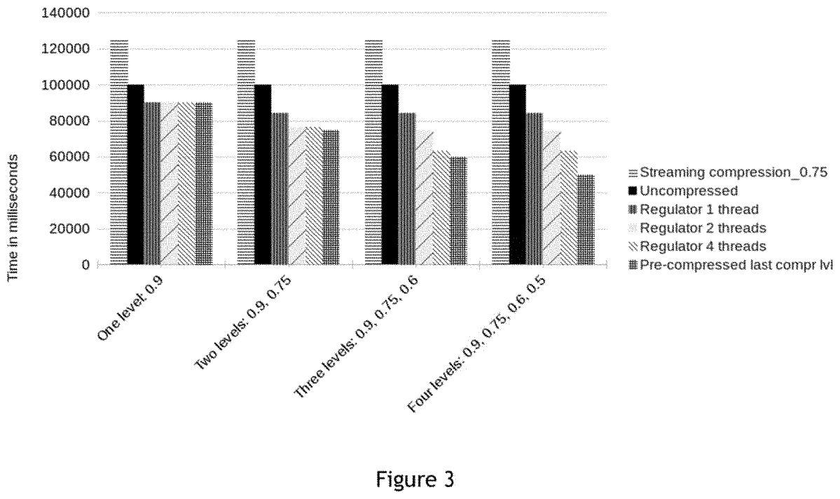

FIG. 3 shows the time to completion when using a compression effort regulator according to embodiments that dynamically targets lower total transmission time. The figure shows how the regulator performs with a different number of compression levels and threads. The compression ratios for the different levels are 0.9, 0.75, 0.6, and 0.5. The network transfer speed was 1 MB/s.

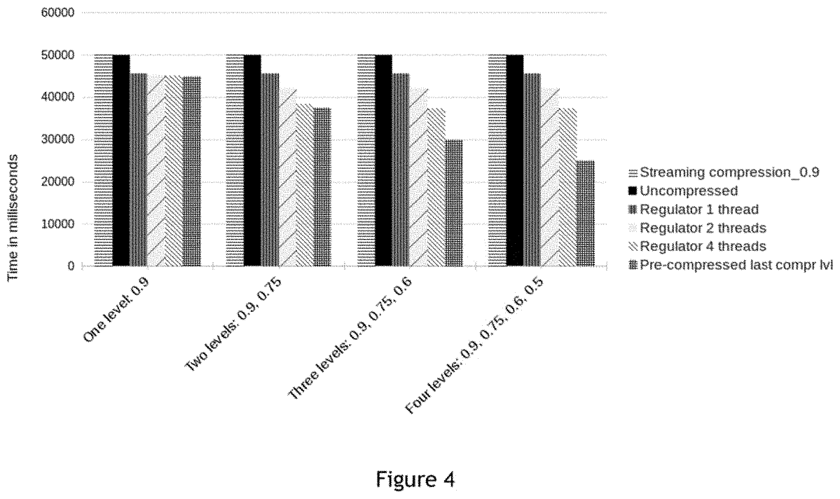

FIG. 4 shows the time to completion when using a compression effort regulator according to embodiments that dynamically targets lower total transmission time. The figure shows how the regulator performs with a different number of compression levels and threads. The compression ratios for the different levels are 0.9, 0.75, 0.6, and 0.5. The network transfer speed was 2 MB/s.

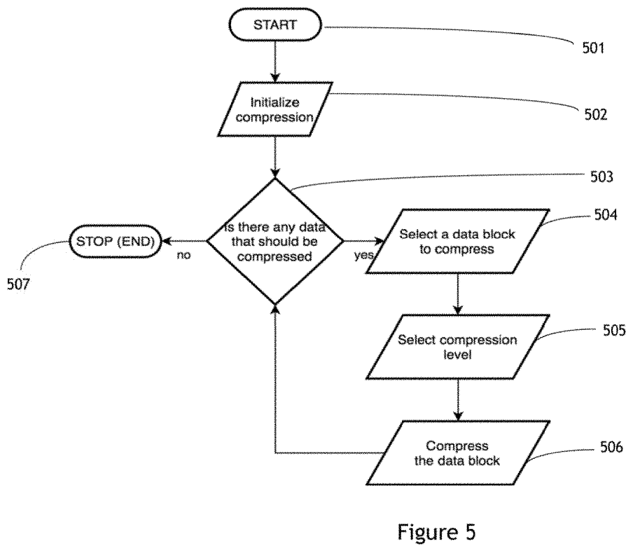

FIG. 5 shows the compression process of a regulator according to embodiments.

In step 501, the compression process begins.

In step 502, the compression process is initialized.

In step 503, it is determined if there is any data to be compressed.

In step 504, a data block is selected for compression.

In step 505, a compression level is selected.

In step 506, the data block is compressed.

In step 507, the compression process ends.

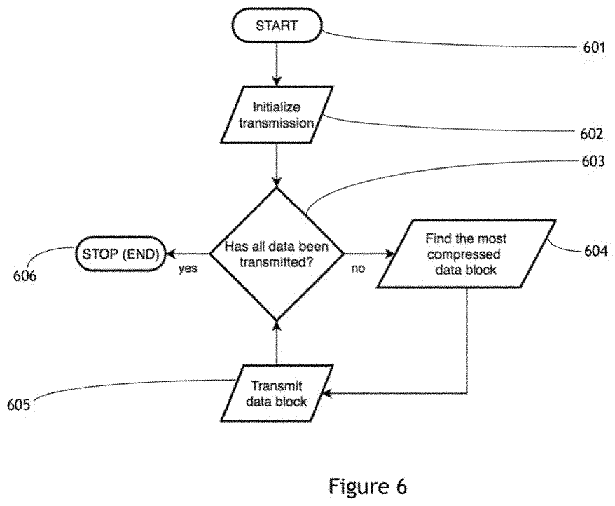

FIG. 6 shows the transmission process of a regulator according to embodiments.

In step 601, the transmission process begins.

In step 602, the transmission process is initialized.

In step 603, it is determined if all data has been transmitted.

In step 604, the most compressed data block is found.

In step 605, the data block is transmitted.

In step 606, the transmission process ends.

Some of the steps in FIGS. 5 and 6 are described in more detail below.

Step 504, “Select a data block to compress”:

Generally, select uncompressed data blocks, or failing that, select data blocks that have been lightly compressed.

Optionally, using a model for compression speed, optimize for sending well-compressed data blocks in-order by selecting a later data block to compress so that the compression operation finishes just before the transmission process is ready to send it. This depends on having decided on a compression level to use.

Optionally, select a data block that has already been compressed in order to compress it more. An uncompressed version of the data block can be kept available for this purpose and other purposes. If a data block compressed at a higher level, i.e. at level+n, becomes equal to, or larger than, an existing version of the same data block, i.e. at level+0, the version of the data block at level+n is discarded and no more attempts may be made to compress that data block at level+n. However, the same data block can still later be selected for compression at level+n+1.

Step 505, “Select a compression level”:

Generally, if compression at a compression level can be completed fast enough to continuously be able to provide data to saturate the transmission speed, then pick that compression level or a high enough level to achieve a balance.

Generally, over time, before transmission, the data blocks will have been compressed to a level that converges to be stable, or to be a mix of two adjacent compression levels with a ratio between them. This can be estimated by counting how many available data blocks are available at a compression level. For instance, if 5 data blocks are available at compression level K, then compression level K+1 seems a reasonable compression level for the next data block to be compressed.

When a data block has been compressed, statistics for the compression speed and ratio of that data block is updated and stored temporarily. This enables the building of a model for the compression speed and ratio at relevant compression levels. When estimating the speed and ratio of a new level it can be based on the current levels speed/rate, and be adjusted with the relative speed/rate difference between the compression levels in a general case.

Compute resources may vary over time, leading to the optimal compression level varying over time.

Transmission speed may vary over time, also leading to compression level varying over time, as compression operation then ideally has a different amount of time available before a compressed packet is transmitted.

In order to have enough compressed data available in case transmission speed increases, X seconds of data that can be sent can be kept available at a reasonably compressed level. That is, the ideal time for compression to finish for a block that is likely to be sent soon, is some time before the likely time that the transmission is ready to begin, in order to have a window for supporting an increase in transmission speed. This means that the ideal compression level for a block is lower than the level which would result in the compression of the block finishing just as the transmission process would be ready to send the block, and how much lower depends on how much buffer is ideal for covering cases where the transmission speed is about to increase.

A more detailed implementation is as follows: Assume the transfer rate is R bytes pr. second and the earlier compression time for a block is T seconds at compression level Cn. If it is known (ahead of time, or from earlier in the transfer) that compression at level Cn+1 takes T2 for a block, then the extra buffer size must be CL=T2/T larger before going to the next level. In addition, to handle variable transfer rates, only increasing rates can cause uncompressed data to be sent. To cover a doubling of the transfer rate R the extra buffer must be RC=2 times larger as well. To cover a drop in compute resources by half the extra buffer must also be CC=2 times larger. Finally, the compression rate at the next level should be better. If the rate at Cn was RC1 and the rate at Cn+1 is RC2 then the extra buffer must be CRate=RC2/RC1 larger (CRate can be statically set ahead of time if unknown). In total the extra buffer size at compression level Cn (and higher if any) must be CRate*RC*CC*CL or larger in total. Since this assumes the transfer rate increases, compression time goes up and compute resources go down at the same time the actual buffer size can be tweaked based on the variability of the system and the desired safety margin. Thus, the compressed buffer at level Cn must sustain a transfer time of around CRate*RC*CC*CL*T at the current compression level Cn before starting to compress at Cn+1. Note that this check is recursively performed for all the compression levels starting at C₁ for each block that is selected for compression, taking into account changes in the transfer speed, compression speed, compression rate and compute resources.

Step 506, “Compress the data block”:

When the process starts to compress a data block, store a timestamp and a compression level. This can be used to estimate when the compression operation for that block will finish.

Optionally, this process can be cancelled if the transmission process runs out of available data blocks to transmit.

Step 604, “Find the most compressed data block”:

Attempt to select a data block that is compressed at a high level, and failing that select a data block that is compressed at a less high level.

Sometimes no compressed blocks are available, in which case an uncompressed data block may be sent.

Sometimes, no data blocks at all are available due to them being kept busy in a compression operation, in which case a compression operation may be cancelled, and that block may be sent in its previous state (less heavily compressed or uncompressed). Due to technical constraints, a process of compression may have finished on data that has already been sent in a previous state, in which case sending the further-compressed data block is not necessary.

Step 503, “Is there any data that should be compressed”:

Generally, a data block should be compressed if compressing it would finish before the time where it would ideally be transmitted.

There are cases where stopping compression operations before the transmission operations for all data blocks has finished. For instance, if the transmission process is about to finish transmitting the second-to-last data block, then starting a new compression operation on the last data block is typically not useful. In this way it is possible to calculate when it is optimal to choose not to start any more compression operations on data packets. If no data blocks are available for which (compression or) a higher level of compression could be completed before the ideal time to start transmitting said data block, then no such operation should start. It may also be beneficial to not start compression operation on packets where doing so would result in packets being sent out of order. It may however in some cases be beneficial to start a compression operation on a data block, even though that compression operation would not finish before the ideal time to start transmitting that data block, if the compression operation is estimated to reduce the size of the data block so significantly that the delay of stalling is smaller than the reduction in transmission time caused by heavier data compression.

It may be determined to not compress data when a model can be used to estimate that the compression operation would lead to stalling and/or a change in the order in which data blocks are transmitted. This depends on what the optimal behaviour is for the receiver. For instance if the receiver is dependent on decompressing data quickly and in-order, then sending packets in-order may be more important than optimizing transmission time by sending the most compressed available data packet.

Accordingly, embodiments provide a compressor and transmitter of data blocks over a transmission channel.

Embodiments also include a receiver of the data blocks that are transmitted over the transmission channel.

The receiver may be able to automatically determine how to decompress each received compressed data block, without being provided with additional data that indicates how to decompress each compressed data block. Alternatively, additional data may be included in each transmitted data block that allows a receiver to determine how to decompress the data.

The compression process may split a file into data blocks that must be made available in-order before they can be decompressed. For instance, it is possible to have data compression that functions in such a way that if the decompression process has received data blocks numbered #1, #2 and #4, it may be able to decompress data blocks #1 and #2, but have to receive data packet #3 before being able to decompress data blocks #3 and #4.

Data blocks may be transmitted in-order or out of order, to be reassembled in-order at the receiver.

The receiver may decompress the data (immediately or later), or keep data in its compressed state, or further compress data before being storing and/or processing it.

Aspects of embodiments are also described below.

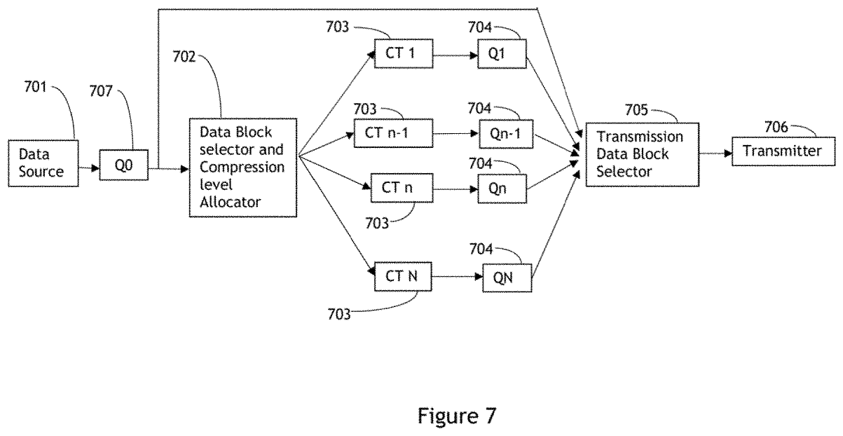

FIG. 7 is a schematic diagram of processes that are performed according to an embodiment.

There is a data source 701. The data source may provide data that is divided into data blocks. Alternatively, the data source may provide data in any form and then data blocks generated in dependence on the provided data.

All of the obtained data blocks may be stored in the first queue 707, i.e. Q0.

There is a data block selector 702 that selects a data block for passing to a compression thread. There is a compression level allocator 702 that determines the compression level for each selected data block. The data block selector 702 and compression level allocator 702 may be separate components or the same component.

There may be a plurality of compression threads 703, i.e CT 1 to CT N. The compression threads are arranged in parallel with each other. Each compression thread outputs a data block to one of a respective plurality of compressor output queues 704, i.e. Q1 to QN.

All of the compression threads CT 1 to CT N compress the data blocks that are provided to them. The data blocks in all of Q1 to QN may therefore all have a smaller size than when the data blocks were provided to CT 1 to CT N. The compression ratio of data blocks may increase in the different queues from a minimum amount in Q0 to a maximum amount in QN.

The data blocks in the compressor output queues Q1 to QN are all ready to send. They therefore provide a transmission buffer that reduces the likelihood of the transmission stalling if there is an increase in transmission rate. In response to the transmission rate increasing, and/or being determined to have high variability, the size of the transmission buffer may be increased by reducing the applied compression level so as to increase the number of data blocks in one or more of the compressor output queues 704.

Transmission data block selector 705 may select data blocks in the compressor output queues 704 for transmission. For example, transmission data block selector 705 may select the most compressed data blocks in the compressor output queues 704. Transmission data block selector 705 may also select data blocks in the first queue 707, i.e. Q0, for transmission.

Transmitter 706 transmits the selected data blocks for transmission.

The techniques according to embodiments include a method of transmitting data, the method comprising: obtaining a plurality of data blocks; determining a plurality of values of a transmission parameter for a transmitter; determining a plurality of values of a processing parameter of a processor; determining, for each of the obtained data blocks, one of a plurality of compression levels in dependence on at least one of the determined transmission parameter values at least one processing parameter values; compressing each of a plurality data blocks in dependence on the determined compression level each block; and transmitting the data blocks; wherein: the transmitted data blocks comprise data blocks are compressed with different compression levels; and one of the compression levels is a determination to not compress data blocks such that the method does not compress some of the transmitted data blocks.

The data blocks are transmitted over a transmission time period and a plurality of transmission parameter values are determined at different times over the transmission time period. The transmission parameter values for a transmitter are indicative of the transmission rate of the transmitter. The transmission rate may vary, for example due to a change in bandwidth of the transmission channel. The transmission parameter is therefore a time variant parameter and the transmission parameter values may therefore differ.

Embodiments include any techniques for measuring a transmission rate of the transmitter and determining a transmission parameter values in dependence on the measured transmission rate. For example, the transmission rate may be determined in dependence on a transmission start time for a data block, the size of the transmitted data block and/or a transmission end time for the data block.

Each transmission parameter value may comprises one or more components. Each component may be determined in dependence on one or more of: measurements within the transmitter; a measured transmission rate of the transmitter; a transmission start time for a data block, the size of the transmitted data block and/or a transmission end time for the data block; data received in response to the transmission of one or more data blocks; link information (2G, 3G, 4G, 5G, WIFI, 10/100/1000 Ethernet); TCP/IP settings; ping time; determinations of an instantaneous, maximum, and/or average transmission rate; server and/or receiver provided settings; energy usage for transmission; variability of the transmission rate of a time period; historic data (e.g. for a type of device); geographical data (land/provider); and user settings.

Each component may be additionally, or alternatively, be determined in dependence on one or more of: an acknowledgement generated by “the environment” (such as operating system, an API, a browser, etc) that the data block has finished sending and/or the transmitter may be able to determine an estimate for the speed at which a data packet is currently transmitting (including before a data block finishes transmitting).

In particular, a component of the transmission parameter may be the variability of the transmission parameter, another component may be the minimum determined transmission rate, another component may be the maximum determined transmission rate and another component may be the current determined transmission rate. A transmission parameter with these components would be particularly appropriate for characterising a transmission channel that changes between the transmission rate being low to the transmission rate suddenly increasing to a high transmission rate, and then decreasing again and with the fluctuation in the transmission rate repeating. A high variability in the transmission parameter may result in a determination to decrease a compression level, to increase a buffer of ready to transmit data blocks, so that an increase in the transmission rate does not stall the transmission process.

The plurality of processing parameter values are determined at different times over the transmission time period.

The available computing resources for compressing data may be variable. For example, the processing resources may occasionally be required to perform other tasks and this would change the amount of computing resources allocated for compressing data. The processing parameter is a time variant parameter and the processing parameter values may differ.

Embodiments include any techniques for determining processing parameter values that are dependent on the available processing resources for compressing a data block.

For example, a compression rate of a data block may be measured and a processing parameter value in dependence on the measured compression rate. The compression rate, and/or processing parameter value, may be determined in dependence on a compression start time for a data block, the size of the compressed data block, a compression ratio of the data block and/or a compression end time for the data block.

Each processing parameter value comprises one or more components. Each component may be determined in dependence on one or more of: the available processing resources for compressing a data block; a measured a compression rate; a compression start time for a data block, the size of the compressed data block, a compression ratio of the data block and/or a compression end time for the data block; data retrieved from the environment, such as by API calls obtaining information on any of CPU type, number of CPU cores, number of hardware threads, CPU cache sizes, CPU frequency(s), performance setting, dedicated hardware blocks, thermal envelopes, battery state, AC/battery power, energy usage for compression/compute, historic data and user settings; initial setting data; a model; size of data to be compressed; number of blocks able to be processed; number of blocks that have been compressed but not transmitted; static compression rate estimates for each compression level (e.g. according to a provided model); computed compression rate estimates for each compression level (e.g. according to an updated model); an initial selection of how many threads to use; benchmark results (benchmarks may be run on the transmitting device, or read from a database of benchmarks on similar hardware); data type (for example, processing parameters for a text file and processing parameters image data, may be determined differently); a determination of the available processing resources for decompressing a data block at a receiver of the data blocks (such as compute, RAM, storage, etc.); and received information from the receiver of the data blocks, such as: the amount of processing resources available at the receiver, the progress the decompression at the receiver, remaining data waiting to be decompressed at the receiver, other descriptions of progress of decompression at the receiver, list of codecs available at the receiver and preferences of the receiver.

Each of the compression levels may differ in the amount of processing resources required to compress a data block, the compression time for a data block and/or the compression ratio of a data block. Each compression level may correspond to the use of a specific compression algorithm and/or specific compression parameters; and all of the compression levels correspond to the use of a different compression algorithm and/or compression parameters.

One of the compression levels may be a determination to not compress data blocks. This compression level results in data blocks in Q0 being selected for transmission.

Embodiments include a regulator. The regulator may execute a model/algorithm that is executed in order to determine which data blocks are selected for compression, the compression level of each data block, and when each data block is transmitted.

An estimated available compression time for a data block may be determined in dependence on a transmission parameter value and/or a processing parameter value. A compression level for the data block may be determined that is the compression level that provides the largest compression ratio within the estimated available compression time.

The estimated available compression time may be dependent on an estimated transmission time of one or more data blocks. The estimated available compression time may be determined as substantially the same as, or less than, the estimated transmission time. The estimated transmission time may be dependent of on the number and/or size of data blocks in one or more of the compressor output queues. The estimated transmission time may be determined in dependence on an estimated transmission end time of a block currently being transmitted and the estimated transmission time of blocks in one or more of the compressor output queues. The compression level for each data block may be determined in dependence on the estimated transmission time.

The data block selector 702 may select a data block for providing to a compression thread. Each data block may be selected in dependence on at least one of the determined transmission parameter values and at least one processing parameter values.

The compression level allocator 702 may determine the compression level for each selected data block in dependence on at least one of the determined transmission parameter values at least one processing parameter values.

The data block selector 702 may select data blocks from Q0. The data block selector 702 may also select data blocks in any of queues Q1 to QN for further compression. QN comprises the most compressed data blocks. Data blocks in QN may selected by the data block selector 702 for further compression if it is determined to create a new compression thread and corresponding new queue, i.e. CT N+1 and QN+1, for applying a larger compression level.

The model/algorithm may be constructed in dependence on the determined processing parameter values and the determined transmission parameter values. The model/algorithm may be used to determine which data blocks are selected and/or the compression level for each selected block. Statistics may be obtained on one or more of compression times, compression ratios, transmission rates and, optionally, other characteristics. The model/algorithm may be constructed in dependence on the statistics. In particular, statistics may be obtained for compression operations at each compression level. The model/algorithm may use these statistics to determine expected compression times and/or compression ratios for data blocks at each compression level. The model/algorithm may also estimate expected compression times and/or compression ratios for data blocks at a new compression level in dependence on the statistics of one or more existing compression levels.

All of the determinations of the model/algorithm may be dependent on the goal of determining compression levels for the data blocks that minimise the total transmission time period for the data blocks.

As shown in FIG. 7, the processor may perform a plurality of compression operations. Each data block is provided to at least one compression operation and each compression operation is arranged to compress a data block in dependence on a different compression level. Each compression operation comprises one or more compression threads and a compressor output queue. The one or more compression threads are arranged to compress a data block and then provide the compressed data block to the compressor output queue. In particular, a compression operation may comprise a plurality of compression threads that act in parallel to each other to compress different data blocks. The plurality of compression threads are arranged to output compressed data blocks and then provide the compressed data blocks to the same compressor output queue.

Each compressor output queue may comprise a plurality of compressed data blocks. Versions of the same data obtained block may be simultaneously compressed, with different compression levels, in a plurality of the compression operations. A data block may be removed from a compressor output queue if another compressor output queue comprises a version of the same obtained data block at a higher compression level.

The transmitter 706 transmits selected data blocks for transmission. One or more of the selected data blocks for transmission may be from Q0 and one or more of the selected data blocks for transmission may be from any of Q1 to QN.

The selection of a data block for transmission may be dependent on one or more of: the compression level and/or compression ratio of the data blocks in the compressor output queues; order of the data blocks; a request for a data block; and values of the transmission parameter. For example, a receiver may require a specific data block before it can decompress other data blocks that have been received. The receiver may send a message to the transmitter asking it to prioritise the transmission of the required data block and the transmitter determine to select the requested data block for transmission next.

Embodiments also include compressing and storing data blocks in advance of the transmission process starting. When the transmission process starts, the stored compressed data blocks may be retrieved and transmitted. The compression and transmission process according to embodiments may therefore retrieve and transmit compressed data blocks from a memory, in addition to the recently compressed data blocks in Q1 to QN and the data blocks in Q0.

Embodiments also include estimating a reduction of transmission time due to a compression operation on a data block before the compression operation of the data block has finished. A determination may then be made to allow the transmission of data to stall so as to allow a compressed data block by the compression operation to be transmitted if waiting for the compression operation to finish provides a sooner completion of data transmission than if a version of the same data block, that has not been compressed by the compression operation, is transmitted without the transmission of data stalling.

Embodiments also include receiving one or more sets of data blocks for transmission. For example, a second set of data blocks may be received before the transmission of the first set of data blocks has been completed. The compression and transmission scheme may be recomputed in response to more data blocks being received.

The obtained data blocks have may different sizes. Each obtain data block may be a file or part of a file.

It may not be possible to further compress some types of obtained data blocks. This may be, for example, because an obtained data block is already heavily compressed or because the data block is encrypted. Embodiments include transmitting these data blocks without further compressing them.

Embodiments include a computing system with one or more processors and one or more transmitters arranged to compress and transmit data blocks according to any of the above described techniques of embodiments.

Embodiments include a computer program that, when executed by a computing system, causes the computing system to perform any of the above described techniques of embodiments.

Embodiments are particularly effective at reducing an overall transmission time of data when the transmission rate of the data, and/or the available processing resources for compressing data, vary over the time period that the data is transmitted.

The number of compressor output queues, N, may be in the range 1 to 100.

A typical block size may be between 100 kb to 100 Mb.

The applied compression ratios by the compression levels may be between 0.1 and 0.99.

Typical applications of embodiments may include the transmission of data from a server to an app, the transmission of data from an app to a server, the transmission of data from a server to another server, the transmission of data from a web client to a server (i.e. uploading on a web page) and the transmission of data from a server to a web client (i.e. downloading on a web page). Embodiments are particularly appropriate for the simultaneous uploading of multiple files, as well as files being split into data blocks before being compressed/transmitted. The files may be, for example, photographs uploaded from an app to an e-commerce portal.

Further aspects of embodiments are described below.

As described above, metadata may be associated with each data block. Each file or object being transmitted (either as a single data block or as multiple data blocks) may have a metadata header that comprises the information needed for determining the size, type, and/or object ID. This enables the receiver to determine the correct way to parse headers for blocks belonging to the received file or object.

Each compressed data block may comprise a metadata header that comprises the information needed for determining how to decompress the data. The metadata may contain any of information about the ordering of the data blocks, a reference to an object that the data block is a part of, and parameters that describe an appropriate decompression process.

The content of the metadata may depend on the specific application. For example, if the transmitter is configured to transmit data blocks in their correct order, then the metadata may not comprise information about the ordering of data blocks. Similarly, if only one file is being sent, then the metadata may not comprise a reference to the file that the data block is a part of. If the compressor codec, or a wrapper, controls the compression level (including the compression level that is a determination to not compress a data block) then the metadata may not comprise this information.

The regulator may determine that a set of data blocks are related to a file or object. Based on this determination, the regulator may determine one or more compression algorithms that are appropriate for compressing the set of data blocks given the type of file or object. The regulator may also determine which data blocks should be selected for transmission, and also which data blocks should be compressed. This is because a compression algorithm may require data blocks to be compressed in order. A wrapper may perform the actual block selection in dependence on determinations by the regulator.

The above described queues that the regulator uses, i.e. Q0 to QN, may exist only as abstract concepts, and can be implemented with other structures or methods.

A file or data object can be split into a plurality of data blocks before being processed and/or transmitted according to the techniques of embodiments. Embodiments include splitting a file or data object into data blocks in such a way that both the compression operations on the data blocks, and the transmission of data blocks, are performed efficiently. In particular, embodiments include a wrapper handling the splitting of a file or object into a plurality of data blocks, the order the data blocks are processed in and the adding of any required metadata needed by the receiver.

A file or data object may be split into a plurality of data blocks and the compression state of the data blocks may change over time. The order that the data blocks are transmitted in may be dependent on their compression states. However, when the transmitter is about send an uncompressed data block, the state of other data blocks belonging to the same file might imply that a different uncompressed data block (of the same file) should be sent. Such a determination may be handled by the wrapper.

Embodiments include determining appropriate compression levels for data blocks in dependence on the results of the applied compression operations. For example, if compressing a data block at a higher compression level makes the compressed data block larger then than an existing version of that data block, then the version of the data block with the higher compression level may be discarded. This data block may be marked so that it will not be selected for compression at that level again. This means that incompressible blocks will not be added to any queue for compression after such a determination. For example, this may occur with data blocks of already compressed data or encrypted data.

If it is known that a data block is incompressible, the data block may be marked so that it cannot be selected for compression. If a data block can only be compressed by a specific algorithm, or compression level, it may be marked that it cannot be compressed at all levels except the ones that are capable of handling this specific data block type. For instance, a data block of an encrypted file can normally only be compressed by a compressor/wrapper that has access to the decryption key. Further, a data block of a zip file can normally only be compressed by a compressor/wrapper that can decompress the zip file before recompression. Data blocks of such files might not be compressible at low compression levels, because significant extra resources may be required in order to achieve compression ratio improvements.

In situations where there are no data blocks left that can be compressed at a specific compression level, the next compression level may be used, unless it is determined that the data blocks can be compressed at that higher level by the regulator. Accordingly, some compression levels may only support data blocks of specific files or data types, and some compression levels may not be available for data blocks of specific files or data types.

Embodiments include techniques for splitting files and objects into a plurality of data blocks. Some types of files and objects can be split in into data blocks without this affecting the ability to compress them. For example, text files, html, log files, XML, 16/32 bit BMP images, PPM, PGM, WAV and many others can be split into data blocks that can be compressed independently.

Other types of files may have a strong internal structure that can only be known by sequentially iterating through the data. Files with this property can still be compressed by re-encoding the same structure in a more efficient way. However, this re-encoding may not be possible if the re-encoding is started at a random point in the file and the re-encoded need to operate in a specific way.

Embodiments include splitting a file or object into data blocks, by a splitter, in dependence on the type of file. This enables efficient compression of data blocks by the regulator.

The splitting of files and objects into data blocks may be dependent on the requirements of a compression algorithm, and may, therefore, cause dependencies between data blocks for the progression of compression-decompression operations.

The operations of a splitter/compressor may set requirements on the order that the data blocks are selected for transmission. For example, a requirement may be that uncompressed blocks are transmitted in a particular order. Similarly, a requirement set by the splitter/compressor may be that data blocks are selected in a particular order for compression. These requirements may only affect which data blocks, within each compression level, are selected and not if the compression process is to take place. If compression is to be performed, when compression is performed and the compression level applied to data blocks may still controlled by the regulator. Data blocks that, are or have been, transmitted may be marked so that the splitter/compressor does not attempt to select them again. Note that the queue of data blocks presented can be a logical construction, and be implemented with other structures or methods. The splitter may determine the order that data blocks are sent to each compression level and/or the order that blocks at each compression level are transmitted.

The splitter may split files/objects in different sized data blocks.

The splitter may create data blocks wherein the data is in a different order than the original data.

The splitter may add metadata to the data blocks. For example, the data type of the file or object may be sent to the receiver as metadata in each data block. If the datatype allows it, this information may be sent as extra metadata that is not included in each data block.

The data type, or file type, of a file or object may be used to determine which algorithm(s) are used to compress data of that type. The splitting of such a file or object into data blocks is impacted by the workings of the appropriate compressor algorithms. The workings of the compression algorithms, and the progress of compression of data blocks belonging to a file or object, may determine the order in which the data blocks belonging to that file or object are transmitted and/or compressed.

Embodiments include splitting complex data objects into data blocks in a number of different ways. These include container-based block splitting, natural block splitting, fixed sized blocks and smart blocks.

In container-based block splitting some files/objects consist of several types of data. For example, a TIFF file consists of multiple data types as well as metadata. A TIFF file contains one or more images, and there are multiple formats for those images, some of which are compressed and some of which are uncompressed. Then each of the internal data containers can be viewed as a new object that might be split, if needed, into more blocks based on their type.

In natural block splitting, the file format has natural splits that can be used to determine how a file or object is split into data blocks. For example, restart markers are unique symbols in the jpeg data stream that can be identified without any context information. This enables encoders and decoders to decode smaller chunks independently. The same markers can be identified very quickly and used to determine data blocks.

With fixed sized blocks, a file or object is split into blocks of fixed size, say 64 KB, and no prepossessing or analysis of the data is needed.

With smart blocks, a block-aware compressor may be implemented. The compression algorithm may be aware of the use of multiple compression levels of blocks. In dependence on the compressor, data blocks can be determined, and prepared, that contain either uncompressed or compressed chunks of data. The compressor can then maintain the extra state needed to apply more complex compression strategies to each block, as it has the context of the data beyond each block. Moreover, it can also include metadata like the compression level used, if any, so that this metadata does not need to be appended to each data block at a higher level. By letting the compressor encode this data it may also be compressed and/or combined to reduce overhead.

Embodiments include the regulator estimating the remaining time that is required to send all the data, based on the current transmission parameters, the total amount of data that is available but has not yet been transmitted, and the average compression ratio so far. The regulator can provide this estimate to other processes (user feedback, receiver feedback, compression algorithm), so that they may take actions based on this. For example, if a user transfers an image, and it is very slow, the user may choose not to transfer more images. If uploading is very fast, the user might choose to transfer more images.

Similarly, a program or process could make similar choices on behalf of a user, based on the provided estimate for the current remaining transfer time.

For some types of data, such as images, sound, video, 3d models, 3d points, 2d points, textures, sensor data, and others, it can be beneficial to compress in a way that loses quality/precision/resolution/detail, since then the time spent on transmission and/or computation is reduced. Lossy compression is compression that loses quality or otherwise loses data, but the goal is for the loss of quality to be minimal, insignificant, or even imperceptible.

There are use-cases where loss of quality of data is not desirable. Further, there also exist types of data where loss in quality is not reasonable or meaningful, for instance text, computer code, and certain types of metadata. For some data types it is more important to have a limited time window between when the data was created and sent, and when the data was decompressed by the receiver. For instance, sensors sending real-time data like temperature, pressure, light measurements or images, where there might be some compute available for compression. Even in cases where the amount of resources for compression is not always sufficient, it can still be applied to parts of the data, leading to an overall reduced amount of transited data. The regulator according to embodiments may then improve the quality of service by providing compression.

Embodiments therefore include using either lossless or lossy compression techniques. Whether lossless compression is used or lossy compression is used may be dependent on the data type.

Some data may have a timing requirement. For example, the data may have a “time” associated with it so that the data should not finish decompressing later than X milliseconds after the “time” of the data. The goal is to have the highest quality data possible available after decompression has completed, within a maximum latency. In this case the regulator may discard blocks that are too old.

Further, for some data types, such as images, there exists ways to compress where the data that is produced early in the process can be used to decompress into a lossy version of the whole data object, and over time more compressed data can be added until the decompressed version's quality is maximum, i.e. it is no longer lossy compression. In this way the most amount of data/quality can be transmitted in the shortest amount of time, given the computing and transmission constraints. This process may attempt to send as much data as possible without increasing the transmission time beyond some limit. On the receiver side, the receiver may provide a preference that the process will stop after a certain amount of time and/or effort has been applied on a compression task, or when a quality requirement has been met. On the server side, the server may cut off work when determining that continuing towards higher quality is no longer beneficial, with regard to its own resource availability and parameters, or with regard to parameters provided by the receiver or a model created on behalf of the receiver. For instance, this can happen if a user scrolls away from a picture after it has been presented in reduced precision.

Since the regulator may know the estimated remaining time to send all data, and the current available computing resources, it can influence the amount of loss in a lossy compression algorithm. That is, the regulator has the capability of being used to change the quality parameter. It can do this by increasing the quality as the remaining time to send all data is reduced, either by increased compression effectiveness or by increased transmission rate, or both.

Increased compression effectiveness can be either that more computing resources are being used for compression (higher compression levels are selected by the regulator), or that the compression algorithm was more effective at compressing recent data. Similarly, if the remaining time to send all data is increased, the quality will be reduced.

In some applications it is beneficial if the receiver decompresses the highest possible quality of lossy compressed data, given the combined transmission and computing constraints both on the sender and receiver side.

Embodiments include a number of modifications and variations to the techniques described herein.

The transmitted compressed data may need to be decompressed by a receiver of the data. If the processing resources at the receiver are restricted, for example due to the receiver being a mobile telephone, the rate at which the received data can be decompressed may be a restriction on the effective transfer rate of uncompressed data at the transmitter to uncompressed data at the receiver.

Embodiments may therefore be directed towards minimising both the overall transmission time and decompression time of data. For example, the overall transmission time and decompression time of data may be reduced by the receiver sending a request to the transmitter for a lower compression level to be used. The transmitter may use the requested lower compression level even though it is capable of transmitting data at a higher compression level with a lower transmission time. The faster decompression that is possible at the receiver may then reduce the overall transmission time and decompression time of data. Accordingly, the compression levels may be determined in dependence on values of a processing parameter at the data decompressor on the receiving side of the transmission channel in addition to, or instead of, processing parameters of the data compressor on the transmission side.

Data packets for transmission as TCP/IP or UDP packets, as well as other forms of data packets, over a network may be determined in dependence on data blocks determined according to embodiments.

Embodiments also include the compression of data for any application.

The flow charts and descriptions thereof herein should not be understood to prescribe a fixed order of performing the method steps described therein. Rather, the method steps may be performed in any order that is practicable. Although the present invention has been described in connection with specific exemplary embodiments, it should be understood that various changes, substitutions, and alterations apparent to those skilled in the art can be made to the disclosed embodiments without departing from the spirit and scope of the invention as set forth in the appended claims.

Methods and processes described herein can be embodied as code (e.g., software code) and/or data. Such code and data can be stored on one or more computer-readable media, which may include any device or medium that can store code and/or data for use by a computer system. When a computer system reads and executes the code and/or data stored on a computer-readable medium, the computer system performs the methods and processes embodied as data structures and code stored within the computer-readable storage medium. In certain embodiments, one or more of the steps of the methods and processes described herein can be performed by a processor (e.g., a processor of a computer system or data storage system). It should be appreciated by those skilled in the art that computer-readable media include removable and non-removable structures/devices that can be used for storage of information, such as computer-readable instructions, data structures, program modules, and other data used by a computing system/environment. A computer-readable medium includes, but is not limited to, volatile memory such as random access memories (RAM, DRAM, SRAM); and non-volatile memory such as flash memory, various read-only-memories (ROM, PROM, EPROM, EEPROM), magnetic and ferromagnetic/ferroelectric memories (MRAM, FeRAM), phase-change memory and magnetic and optical storage devices (hard drives, magnetic tape, CDs, DVDs); network devices; or other media now known or later developed that is capable of storing computer-readable information/data. Computer-readable media should not be construed or interpreted to include any propagating signals.

1. A computer-implemented method of transmitting data, the method comprising:
obtaining a plurality of data blocks;
determining a plurality of values of a transmission parameter for a transmitter;
determining a plurality of values of a processing parameter of a processor;
determining, for each of the obtained data blocks, one of a plurality of compression levels in dependence on at least one of the determined transmission parameter values and/or at least one of the processing parameter values;
compressing each of a plurality data blocks in dependence on the determined compression level each block; and
transmitting the data blocks;
wherein:
the transmitted data blocks comprise data blocks that are compressed with different compression levels; and
one of the compression levels is a determination to not compress data blocks such that the method does not compress some of the transmitted data blocks.

2. The computer-implemented method according to claim 1, wherein the obtained data blocks are transmitted over a transmission time period;
the plurality of transmission parameter values are determined at different times over the transmission time period;
wherein the transmission parameter is a time variant parameter; and
at least two of the transmission parameter values are different.

3. The computer-implemented method according to claim 1, wherein each transmission parameter value comprises one or more components; and
each component is determined in dependence on one or more of:
measurements within the transmitter;
a measured transmission rate of the transmitter;
a transmission start time for a data block, the size of the transmitted data block and/or a transmission end time for the data block;
data received in response to the transmission of one or more data blocks;
link information;
TCP/IP settings;
ping time;
determinations of an instantaneous, maximum, and/or average transmission rate;
server and/or receiver provided settings;
energy usage for transmission;
variability of the transmission rate of a time period;
historic data;
geographical data; and
user settings.

4. The computer-implemented method according to claim 1, wherein the plurality of processing parameter values are determined at different times over the transmission time period;
the processing parameter is a time variant parameter; and
at least two of the processing parameter values are different.

5. The computer-implemented method according to claim 1, wherein each processing parameter value comprises one or more components; and
each component is determined in dependence on one or more of:
the available processing resources for compressing a data block;
a measured a compression rate;
a compression start time for a data block, the size of the compressed data block, a compression ratio of the data block and/or a compression end time for the data block;
data retrieved from the environment, such as by API calls obtaining information on any of CPU type, number of CPU cores, number of hardware threads, number of compression processes, CPU cache sizes, CPU frequency(s), performance setting, dedicated hardware blocks, thermal envelopes, battery state, AC/battery power, energy usage for compression/compute, historic data and user settings;
initial setting data;
a model;
size of data to be compressed;
number of blocks able to be processed;
number of blocks that have been compressed but not transmitted;
static compression rate estimates for each compression level;
computed compression rate estimates for each compression level;
an initial selection of how many compression processes to use;
benchmark results;
data type;
a determination of the available processing resources for decompressing a data block at a receiver of the data blocks; and
received information from the receiver of the data blocks, such as: the amount of processing resources available at the receiver, the progress the decompression at the receiver, remaining data waiting to be decompressed at the receiver, other descriptions of progress of decompression at the receiver, list of codecs available at the receiver and preferences of the receiver.

6. The computer-implemented method according to claim 1, wherein each of the compression levels differ in the amount of processing resources required to compress a data block, the compression time for a data block and/or the compression ratio of a data block.

7. The computer-implemented method according to claim 1, wherein each compression level corresponds to the use of a specific compression algorithm and/or specific compression parameters; and
all of the compression levels correspond to the use of a different compression algorithm and/or compression parameters.

8. The computer-implemented method according to claim 1, further comprising estimating an available compression time for a data block in dependence on a transmission parameter value and/or a processing parameter value; and
determining the compression level for the data block as the compression level that provides the largest reduction in the size of the data block within the estimated available compression time;
wherein the estimated available compression time is dependent on an estimated transmission time of one or more data blocks;
the estimated available compression time is determined as substantially the same as, or less than, the estimated transmission time; and
wherein the estimated transmission time is dependent on:
the number and/or size of data blocks in one or more of the compressor output queues;
an estimated transmission end time of a block currently being transmitted; and/or
the estimated transmission time of blocks in one or more of the compressor output queues and/or the transmission queue; and
the method comprises determining a compression level for a data block in dependence on the estimated transmission time.

9. The computer-implemented method according to claim 1, wherein:
the compression level for a data block is determined in dependence on the available resources for decompression at a receiver of the transmitted data blocks; and/or
a received request for a compression level.

10. The computer-implemented method according to claim 1, further comprising selecting a plurality of data blocks in dependence on at least one of the determined values of the transmission parameter and/or at least one values of the processing parameter;
wherein the compression levels are determined for the selected data blocks; and
at least one of the selected data blocks for compression is one of the data blocks in a compressor output queue.

11. The computer-implemented method according to claim 1, further comprising:
constructing a model in dependence on the determined values of the processing parameter and the determined values of the transmission parameter; and
using the model to determine which data blocks are selected and/or the compression level for each selected block;
the method further comprising:
obtaining statistics on one or more of compression times, compression ratios and transmission rates; and
constructing the model in dependence on the obtained statistics;
wherein the statistics are obtained for compression operations at each compression level; and
the model uses the statistics to determine expected compression times and/or compression ratios for data blocks at each compression level;
wherein the model estimates expected compression times and/or compression ratios for data blocks at a new compression level in dependence on the statistics of one or more existing compression levels.

12. The computer-implemented method according to claim 1, wherein the compression levels for the data blocks are determined in dependence on an algorithm for minimising the transmission time period for the obtained data blocks.

13. The computer-implemented method according to claim 1, wherein the processor is arranged to perform a plurality of compression operations;
each data block is provided to at least one compression operation; and
each compression operation is arranged to compress a data block in dependence on a compression level;
wherein:
each compression operation comprises one or more compression processes and a compressor output queue;
all of the compression processes of a compression operation are arranged to compress a data block and then provide the compressed data block to the compressor output queue; and
each compressor output queue may comprise one or more plurality of compressed data blocks;
wherein versions of the same obtained data block are compressed in a plurality of compression operations at a respective plurality of different compression levels; and
the method further comprises removing a data block from a compressor output queue if another compressor output queue comprises a version of the same obtained data block with a larger compression ratio and/or at a higher compression level.

14. The computer-implemented method according to claim 1, further comprising:
selecting one or more of the obtained data blocks for transmission;
selecting one or more of the data blocks in the compressor output queues for transmission; and
transmitting the selected data blocks;
wherein the selection of a data block for transmission is dependent on one or more of:
the compression level and/or compression ratio of the data blocks in the compressor output queues;
order of the data blocks;
a request for a data block; and
values of the transmission parameter.

15. The computer-implemented method according to claim 1, wherein:
the compression operations are controlled by a regulator;
the regulator determines the performance of the compression operations; and
one or more other processes are controlled in dependence on the determined the performance of the compression operations by the regulator;
wherein the other processes may include any of the selection of a data block for compression, the supply of the obtained data blocks for transmission, the applied compression level, the provision of feedback to a user, the provision of feedback to the receiver and the selection of a compression algorithm.

16. The computer-implemented method according to claim 1, further comprising:
receiving and selecting for transmission compressed versions of one or more of the obtained data blocks.

17. The computer-implemented method according to claim 1, further comprising:
estimating a reduction of transmission time due to a compression operation on a data block, wherein the compression operation of the data block has not finished; and
determining to allow the transmission of data to stall so as to allow a compressed data block by the compression operation to be transmitted if waiting for the compression operation to finish provides a sooner completion of data transmission than if a version of the same data block, that has not been compressed by the compression operation, is transmitted without the transmission of data stalling.

18. A computer-implemented method of transmitting data, the method comprising:
obtaining a first set of data blocks;
determining how to transmit the first set of data blocks according to the method of claim 1;
starting the transmission of the first set of data blocks;
obtaining a second set of data blocks, wherein the second set of data blocks are obtained before the transmission of all of the first set of data blocks is finished; and
determining, according to the method of claim 1, how to transmit the second set of data blocks and the data blocks in the first set of data blocks that have not been transmitted.

19. A computer program that, when executed, causes a computing system to perform the computer-implemented method of claim 1.
